(19) United States
(12) Patent Application Publication
(10) Pub. No.: US 2026/0271358 A1
(43) Pub. Date: Sep. 10, 2026

(54) APPARATUS INCLUDING FET AND INTEGRATED SBD LOCATED OUTSIDE OF FET UNIT CELL

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US)

(73) Assignee: Microchip Technology Incorporated, Chandler, AZ (US)

(21) Appl. No.: 19/556,897

(22) Filed: Mar. 4, 2026

Related U.S. Application Data
(60) Provisional application No. 63/769,557, filed on Mar. 10, 2025.

(51) Int. Cl. H10D 62/17; H10D 8/60; H10D 30/83; H10D 84/87; H10D 30/01

(52) U.S. Cl. CPC H10D 62/343; H10D 8/60; H10D 30/831; H10D 84/87; H10D 30/0515

(57) ABSTRACT

An apparatus includes a field-effect transistor (FET) and a physically and functionally integrated Schottky barrier diode located outside of the unit cell of the FET. A method of making the apparatus is also disclosed. The FET includes a source located at a first end of a volume of semiconductor material, a drain, and a channel for charge carriers moving therebetween. A gate is located adjacent the first end for facilitating controlling movement of the charge carriers through the channel.

### CROSS-REFERENCE TO RELATED APPLICATION

The present U.S. non-provisional patent application is related to and claims the priority benefit of earlier-filed U.S. provisional patent application entitled "JFET with Integrated SBD,” Serial No. 63/769,557, filed Mar. 10, 2025, the entire content of which is hereby incorporated by reference as if fully set forth herein.

### FIELD

The present disclosure relates to field-effect transistors and methods of making them, and more particularly, the various examples described herein concern an apparatus including a field-effect transistor and a physically and functionally integrated Schottky barrier diode located outside of the unit cell of the field-effect transistor, and a method of making an apparatus including a field-effect transistor and a physically and functionally integrated Schottky barrier diode located outside of the unit cell of the field-effect transistor.

### BACKGROUND

A junction field-effect transistor (JFET) is an active, voltage-controlled semiconductor device, in which varying an electrical voltage between a gate and a source controls an electrical current flowing through a semiconductor channel between a drain and the source. Applications for JFETs include amplifiers, switches, resistors, regulators, oscillators, and choppers. It is generally desirable to improve the performance and reduce the cost of JFETs, but it can be difficult to do so.

This background discussion is intended to provide related information, and is not necessarily prior art.

### SUMMARY

Examples provide an apparatus including a FET and a physically and functionally integrated Schottky barrier diode (SBD) located outside of the unit cell of the FET. Examples advantageously provide faster switching speed, lower forward voltage drop, more efficient signal processing, reduced power loss, and improved reverse recovery at lower cost, in smaller and lighter modules, and without requiring an extra mask during fabrication.

In an example, an apparatus may include a volume of semiconductor material, a FET, and a first SBD. The volume of semiconductor material may include a first end, a left side, and a right side. The FET may include a source located at the first end of the volume of semiconductor material, a drain located spaced apart from the source, and a gate located adjacent the first end of the volume of semiconductor material spaced from the source, with the source and the gate being spaced apart to cooperatively define a FET until cell located between the left and right sides of the volume of the volume of semiconductor material. The first SBD may be located at the first end of the volume of semiconductor material and outside of and adjacent to the FET unit cell.

The preceding example may further include any one or more of the following features. The FET may be a JFET, and the JFET may be a planar or a trench JFET. The first SBD may include a Schottky material such as aluminum, titanium, molybdenum, platinum, chromium, tungsten, and combinations thereof. The gate may include spaced apart left and right gates. The source may be located between the gates. The left gate may present a leftmost margin closest to the left side of the volume of semiconductor material. The right gate may present a rightmost margin closest to the right side of the volume of semiconductor material. The FET unit cell may be defined between the leftmost margin of the left gate and the rightmost margin of the right gate. The leftmost margin of the left gate being spaced from the left side of the volume of semiconductor material. The rightmost margin of the right gate being spaced from the right side of volume of semiconductor material. The first SBD may be a left SBD located between the leftmost margin of the left gate and the left side of the volume of semiconductor material. The apparatus may further include a right SBD located between the rightmost margin of the right gate and the right side of the volume of semiconductor material. The first SBD may be a left SBD located outside of the FET unit cell adjacent to the left side of the volume of semiconductor material, and the apparatus may further include a right SBD located at the first end of the volume of semiconductor material and outside of the FET unit cell adjacent to the right side of the volume of semiconductor material. The volume of semiconductor material may comprise an N-type material. The source may comprise an N+ material. The drain may comprise an N+ material. The gate may include a first region comprising a P+ material and a second region comprising a P material.

In another example, a method of making an apparatus may include the following operations. A volume of semiconductor material may be provided including a first end, a left side, and a right side. A FET may be made including forming a source at the first end of the volume of semiconductor material, providing a drain spaced apart from the source, and forming a gate adjacent the first end of the volume of semiconductor material spaced from the source, such that the source and the gate cooperatively define a FET until cell located between the left and right sides of the volume of the volume of semiconductor material. A first SBD may be made at the first end of the volume of semiconductor material and outside of and adjacent to the FET unit cell.

The preceding example may further include any one or more of the following features. The operation of forming the gate may include providing spaced apart left and right gates, such that the source is located between the left and right gates. The operation of forming the left gate may include spacing a leftmost margin of the left gate from the left side of the volume of semiconductor material, and the operation of forming the right gate may include spacing a rightmost margin of the right gate from the right side of the volume of semiconductor material, with the FET unit cell being defined between the leftmost margin of the left gate and the rightmost margin of the right gate. The operation of making the first SDB may include forming the first SBD between the leftmost margin of the left gate and the left side of the volume of semiconductor material. The method may further include making a second SBD at the first end of the volume of semiconductor material outside of the FET unit cell between the rightmost margin of the right gate and the right side of the volume of semiconductor material. The operation of making the first SDB may include forming the first SBD adjacent the left side of the volume of semiconductor material. The method may further include making a second SBD at the first end of the volume of semiconductor material outside of the FET unit cell adjacent the right side of the volume of semiconductor material. The FET may be a JFET. The operation of providing the volume of semiconductor material may be performed so that the first end is planar, and the operations of forming the source and gate may include positioning the source and the gate at the first end, such that the JFET is a planar JFET. The method may further include etching a trench into the first end of the volume of semiconductor material on opposite sides of the trench, and the operation of forming the gate may include providing spaced apart left and right gates in the trench on opposite sides of the source, such that the JFET is a trench JFET. The operation of making the first SBD may include placing a Schottky material on the first end of the volume of semiconductor material, wherein the Schottky material may include aluminum, titanium, molybdenum, platinum, chromium, tungsten, and combinations thereof.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of a first example of an apparatus including a field-effect transistor (FET) and a physically and functionally integrated Schottky barrier diode (SBD) located outside of the unit cell of the FET, wherein the FET has a planar configuration;

FIG. 2 is a cross-sectional elevation view of a second example of an apparatus including a FET and a physically and functionally integrated SBD located outside of the unit cell of the FET, wherein the FET has a trench configuration;

FIG. 3 is a cross-sectional elevation view of a third example of an apparatus including a FET and a physically and functionally integrated SBD located inside of the unit cell of the FET;

FIG. 4 is a flowchart of operations in an example of a method of making an apparatus including a FET and a physically and functionally integrated SBD located outside of the unit cell of the FET (as in the example apparatuses of FIGS. 1 and 2) and/or inside of the unit cell of the FET (as in the example apparatus of FIG. 3);

FIG. 5A is a cross-sectional elevation view of example results of one or more operations in the method of FIG. 4, including the formation of a gate (including left and right gates) and a source;

FIG. 5B is a cross-sectional elevation view of examples results of one or more operations in the method of FIG. 4, including the formation of one or more SBDs located outside of the unit cell of the FET (as in the example apparatuses of FIGS. 1 and 2); and

FIG. 5C is a cross-sectional elevation view of example results of one or more operations in the method of FIG. 4, including the formation of one or more SBDs located inside of the unit cell of the FET (as in the example apparatus of FIG. 3).

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples. The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

A JFET may benefit from an additional antiparallel free-wheeling diode to address a reverse recovery function. In particular, an SBD provides enhanced protection, faster switching, lower forward voltage drop, reduced leakage current, and improved overall performance in various applications. This is particularly useful in high-frequency applications in which fast response times are desirable, such as in radio frequency amplifiers and digital logic circuits, by allowing for more efficient signal processing and reduced power loss compared to a standard PN junction diode. One solution is to use a separate, off-chip antiparallel free-wheeling diode for the JFET.

Examples provide an apparatus including a FET and a physically and functionally integrated SBD located outside of the unit cell to take advantage of fast switching speed and low forward voltage drop which is especially beneficial in high-frequency applications for which fast response times may be desired. Examples advantageously provide more efficient signal processing, reduced power loss, and improved reverse recovery at lower cost, in smaller and lighter modules, and without requiring an extra mask during fabrication.

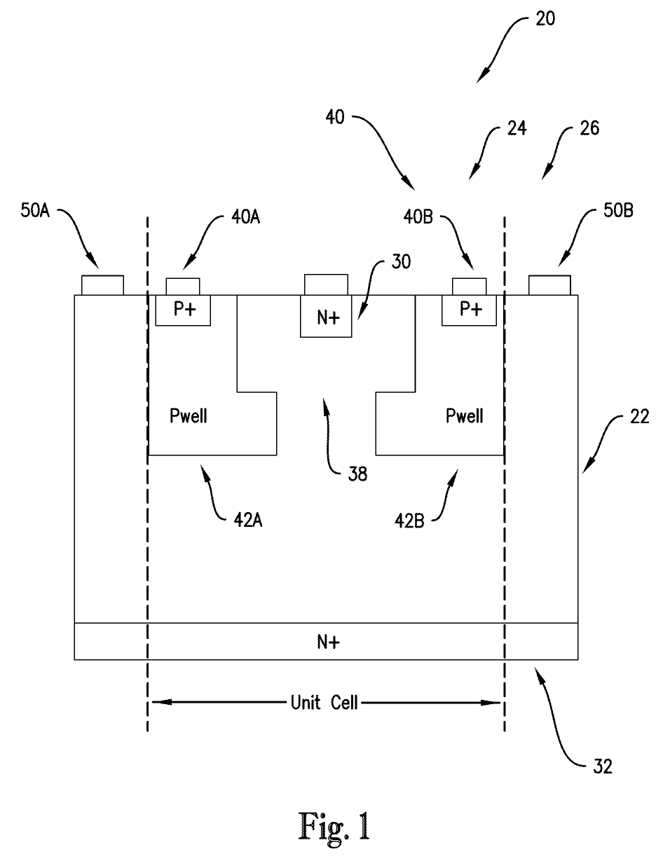

Referring to FIG. 1, a first example of an apparatus 20 is shown including a FET and a physically and functionally integrated SBD located outside of the unit cell of the FET. The apparatus 20 may include a volume of semiconductor material 22, the FET 24, and the SBD 26. The volume of semiconductor material 22 may be a single, continuous volume of semiconductor material and include vertically spaced first and second ends and laterally spaced left and rights sides. The FET 24 may be a JFET and may include a source 30, a drain 32, a channel 38, and a gate 40. In the illustrated example, the gate 40 includes a left gate 40A and a right gate 40B. The left gate 40A may include a left well 42A, and the fight gate 40B may include a right well 42B.

The source 30 may be located at the first end of the volume of semiconductor material 22 between the left and right gates 40A, 40B. The source 30 may provide an entrance for charge carriers (e.g., electrons for N-channel). The drain 32 may be located spaced apart (e.g., at the second end) from the source 30, and may provide an exit for the change carriers. The channel 38 may be a region of the semiconductor material 22 through which the charge carriers move between the source 30 and the drain 32.

The left gate 40A may be located at the first end of the volume of semiconductor material 22 and to the left of the source 30, and may facilitate controlling movement of the charge carriers through the channel 38. The left gate 40A may include a higher doped region which may be partially embedded within or surrounded by a lower doped region or left well 42A. The left well 42A may extend from adjacent to and/or below the higher doped region into the volume of semiconductor material 22 toward the second end. In the example shown in FIG. 1, the left well 42A may include a lower leg that extends toward the right (i.e., toward the channel 38) but not under the source 30. However, according to some examples, the lower leg may extend under the source or rightward even beyond the source. The left gate 40A may present a leftmost margin closest to the left side of the volume of semiconductor material and a rightmost margin closest to the right side of the volume of semiconductor material.

The right gate 40B may be located at the first end of the volume of semiconductor material 22 and to the right of the source 30 and may facilitate (and may cooperate with the left gate 40A in) controlling movement of the charge carriers through the channel 38. The right gate 40B may include a higher doped region which may be partially embedded within or surrounded by a lower doped region or right well 42B. The right well 42B may extend from adjacent to and/or below the higher doped region into the volume of semiconductor material 22 toward the second end. In the example shown in FIG. 1, the right well 42B may include a lower leg that extends toward the left (i.e., toward the channel 38) but not under the source 30. However, according to some examples, the lower leg may extend under the source or leftward even beyond the source. The right gate 40B may present a rightmost margin closest to the right side of the volume of semiconductor material and a leftmost margin closest to the left gate 40A or the left side of the volume of semiconductor material. The gates 40A and 40B may be symmetric and mirror images of one another, although asymmetry and alternative arrangements of similarly shaped gates/wells are within the ambit of certain examples. The channel 38 may pass between the lower legs of the left and right lower doped regions 42A, 42B of the gates 40A, 40B.

The gates 40A, 40B may be shorted or otherwise appropriately electrically coupled.

The FET 24 may define the unit cell and the limits thereof. In the illustrated examples, the unit cell may extend laterally from the leftmost margin or edge (closest to the left side of the volume of semiconductor material) of the leftmost component (in this example, the left well 42A) to the right leftmost margin or edge (closest to the right side of the volume of semiconductor material) of the rightmost component (in this example, the right well 42B). In the illustrated example, the leftmost margin of the well 40A is spaced from the left side of the volume of semiconductor material, and the rightmost margin of the well 40A is spaced from the right side of the volume of semiconductor material. However, according to certain examples, the leftmost and rightmost margins of the wells may correspond (be aligned) with the left and right sides of the volume of semiconductor material, respectively. In some applications, there may be many such FET unit cells arranged in the single, continuous volume of semiconductor material 22, and, further, there may be several SBDs in the single, continuous volume of semiconductor material 22, and some or all of these FETs may share the functionality of some or all of these SBDs. The FET 24 of FIG. 1 is shown with a planar JFET configuration, with the source 30 and gate 40 located at the planar first end of the volume of semiconductor material, which primarily affects the configuration of the left and right gates 40A, 40B.

The SBD 26 may include one or both of a left SBD 50A and/or a right SBD 50B. The left and right SBDs 50A, 50B may be shorted or otherwise electrically coupled. The left SBD 50A may be located at the first end of the volume of semiconductor material 22 and to the left of the FET 24, i.e., between the leftmost margin of the left gate 40A (the left well 42A) and the left side of the volume of semiconductor material, i.e., outside of the unit cell of the FET 24. Additionally or alternatively, the right SBD 50B may be located at the first end of the volume of semiconductor material 22 and to the right of the FET 24, i.e., between the rightmost margin of the right gate 40B (the right well 42B) and the right side of the volume of semiconductor material, i.e., outside of the unit cell of the FET 24. The SBD 26 may include a Schottky material selected from the group consisting of: aluminum, titanium, molybdenum, platinum, chromium, tungsten, and combinations thereof.

The volume of semiconductor material 22 (apart from the components, such as the source 30 and gate 40, implanted or otherwise provided therein) may be an N-type material. The source 30 and drain 32 may comprise an N+ material (i.e., have a higher dopant concentration than the volume of semiconductor material 22). The left gate 40A may include a highly doped region adjacent the gate contact/terminal and a lower doped region that may surround the highly doped region. The highly doped region may comprise a P+ material, and the lower doped region (well 42A) may comprise a P material. The right gate 40B may similarly include a highly doped region adjacent the gate contact/terminal and a lower doped region that may surround the highly doped region. The highly doped region may comprise a P+ material, and the lower doped region (well 42A) may comprise a P material.

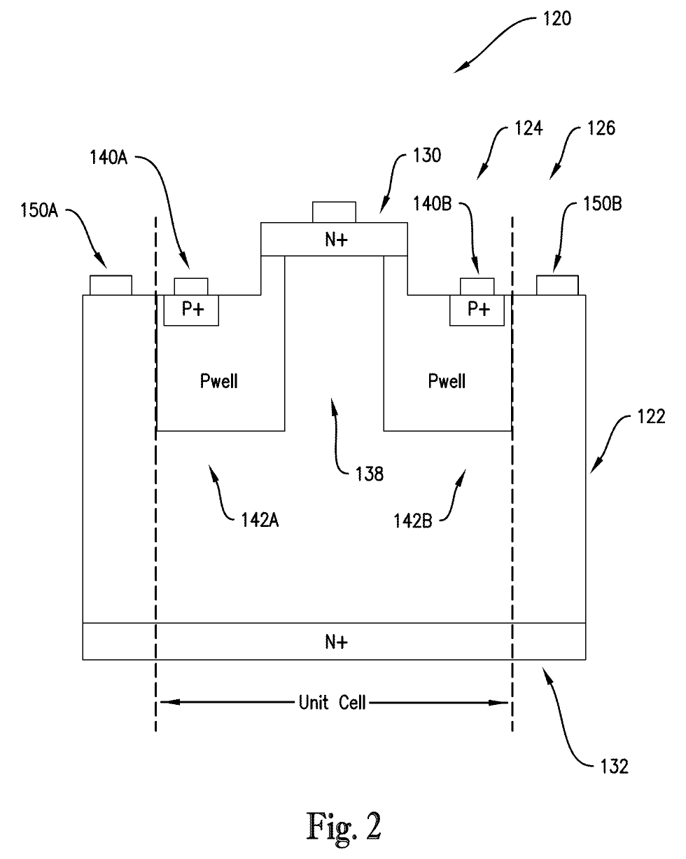

Referring to FIG. 2, a second example of an apparatus 120 is shown including a FET and a physically and functionally integrated SBD located outside of the unit cell of the FET. The apparatus 120 of FIG. 2 may be substantially similar or identical to the apparatus 20 of FIG. 1, except that the FET 124 of FIG. 2 is shown with a trench configuration, which primarily affects the configuration of the left and right gates 140A, 140B. The apparatus 120 may include a volume of semiconductor material 122, the FET 124, and the SBD 126. The volume of semiconductor material 122 may be a single, continuous volume of semiconductor material and include a first end, a second end, a left side, and a right side. The FET 124 may be a JFET and may include a source 130, a drain 132, a channel 138, a left gate 140A (including a left well 142A), and a right gate 140B (including a right well 142B). The SBD 126 may include one or both of a left SBD 150A and/or a right SBD 150B. The left SBD 150A may be located at the first end of the volume of semiconductor material 122 and to the left of the FET 124, i.e., to the left of the left gate 140A (the left well 142A), i.e., outside of the unit cell of the FET 124. Additionally or alternatively, the right SBD 150B may be located at the first end of the volume of semiconductor material 122 and to the right of the FET 124, i.e., to the right of the right gate 140B (the right well 142B), i.e., outside of the unit cell of the FET 124.

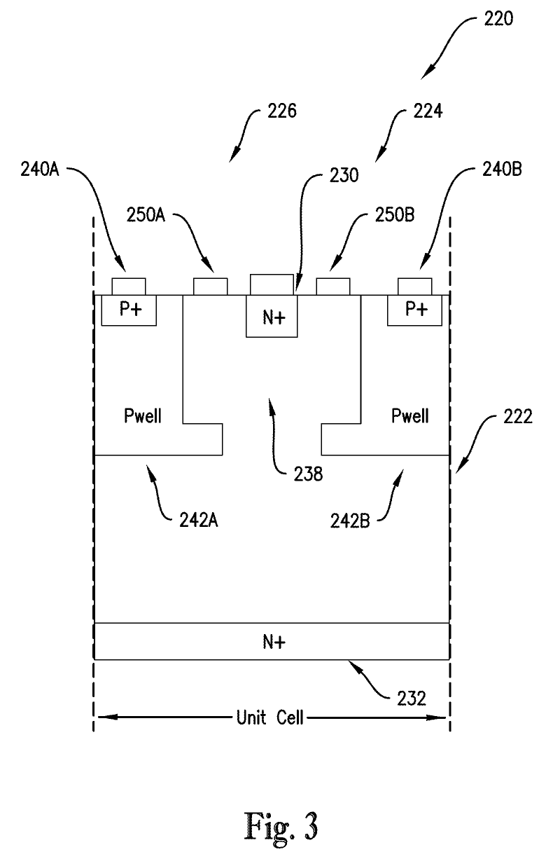

Referring to FIG. 3, a third example of an apparatus 220 is shown including a FET and a physically and functionally integrated SBD located inside of the unit cell of the FET. This configuration, with the SBD located inside of the unit cell, may provide benefits with regard to field-shaping and transient control, improved dynamic ruggedness, and increased breakdown voltage. The apparatus 220 may include a volume of semiconductor material 222, the FET 224, and the SBD 226. The second example of the apparatus 220 may be substantially similar or identical to the first example with regard to the volume of semiconductor material 222 and the FET 224. The FET 224 may include a source 230, a drain 232, a channel 238, a left gate 240A (including a left well 242A), and a right gate 240B (including a right well 242B). The FET 224 may have a planar configuration, which primarily affects the configuration of the left and right gates 240A, 240B.

The SBD 226 may include one or both of a left SBD 250A and/or a right SBD 250B. The left SBD 250A may be located at the first end of the volume of semiconductor material 222 and within the FET 224, i.e., between the left gate 240A (the left well 242A) and the source 230, adjacent and to the left of the source 230, i.e., inside of the unit cell of the FET 224. Additionally or alternatively, the right SBD may be located at the first end of the volume of semiconductor material 222 and within the FET 224, i.e., between the right gate 240B (the right well 242B) and the source 230, adjacent and to the right of the source 230, i.e., inside of the unit cell of the FET 224.

In yet another example, not separately shown, one or more SBDs 50A and/or 50B may be located outside of the unit cell and one or more other SBDs 150A and/or 150B may be located inside of the unit cell, i.e., the example shown in FIGS. 1 or 2 may be combined with the example shown in FIG. 3.

In the various examples, the one or more SBDs 26, 126, 226 of the FETs 24, 124, 224 may each include a Schottky material such as aluminum, titanium, molybdenum, platinum, chromium, tungsten, and combination thereof. The one or more SBDs 26, 126, 226 may each function to prevent the FET 24, 124, 224 from entering deep saturation, thereby improving switching speed by limiting the drain-source voltage (Vds). The one or more SBDs 26, 126, 226 may each shunt away excess electrical current and thereby prevent excessive voltage drop. This is particularly useful in high-frequency circuits such as logic gates, where fast switching is desirable.

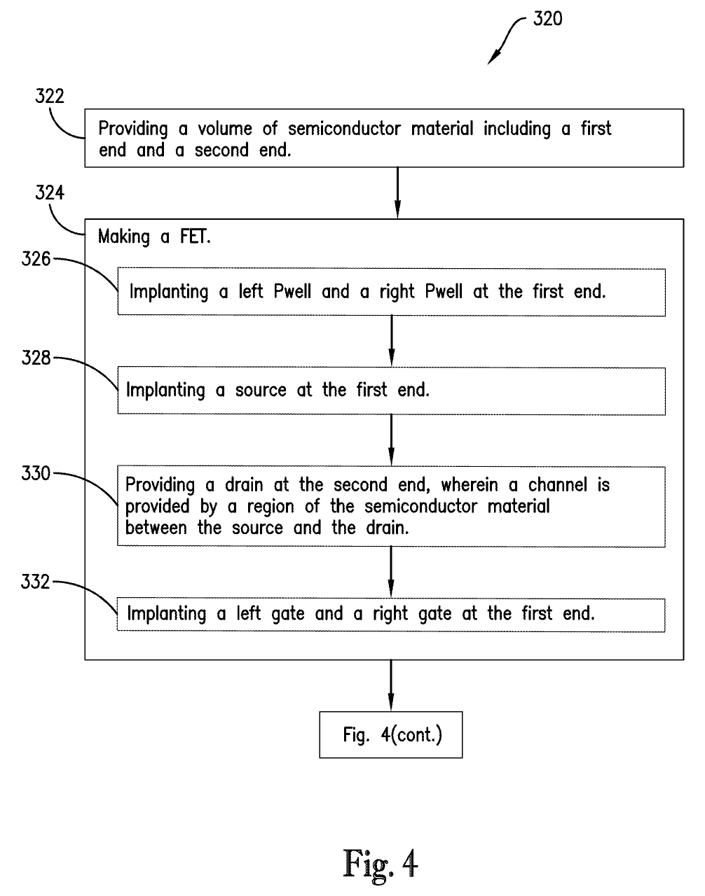

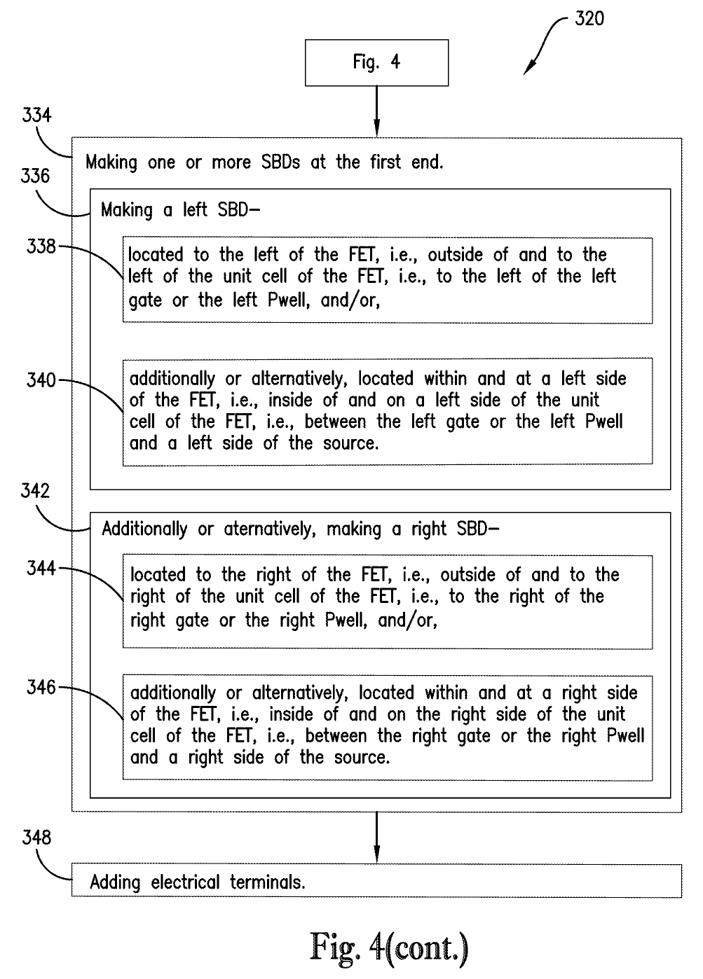

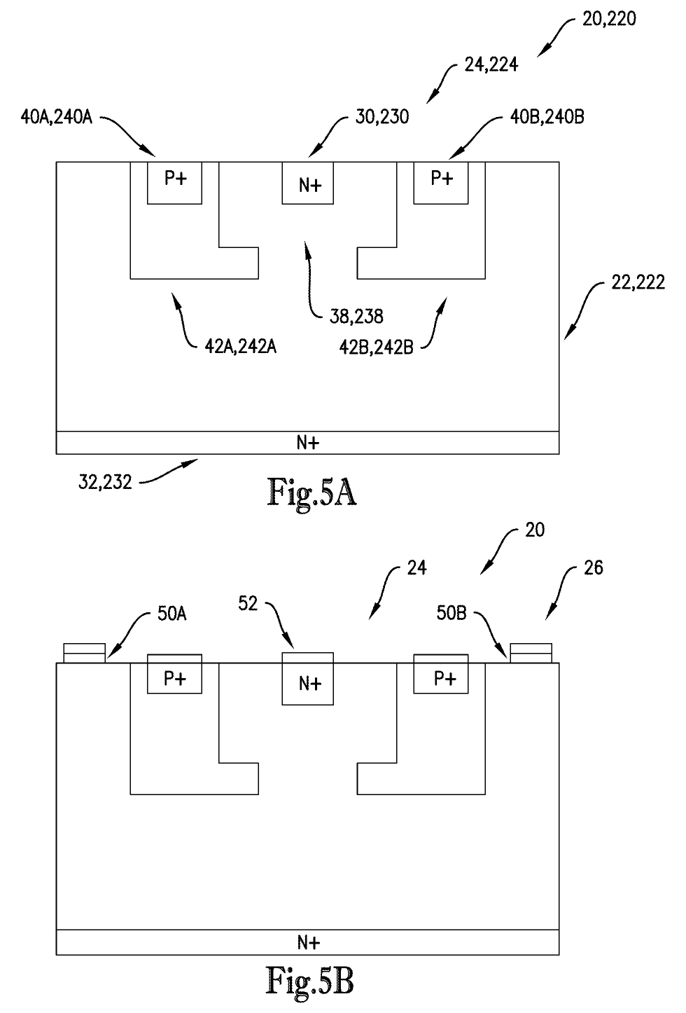

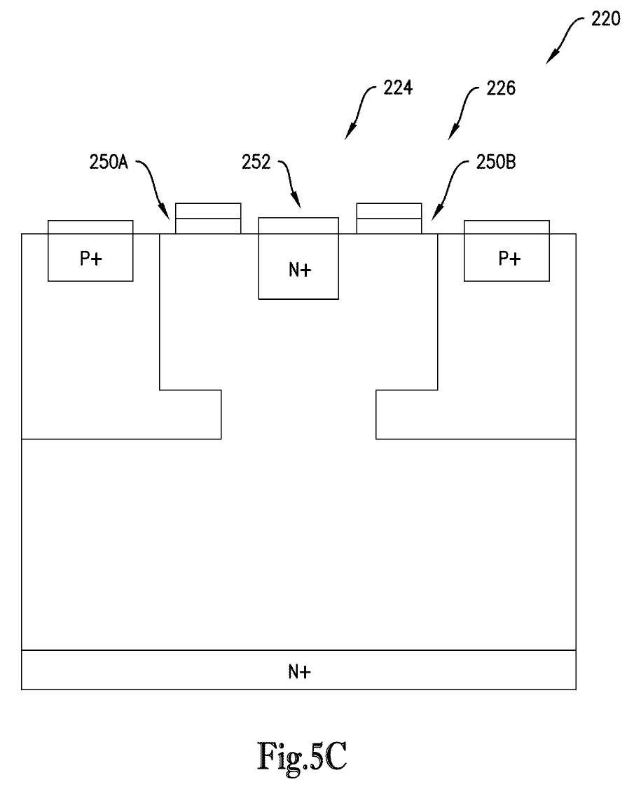

Referring to FIG. 4, an example of a method 320 is shown for making an apparatus including a FET and a physically and functionally integrated SBD located inside of the unit cell or outside of the unit cell of the FET. The method 320 may be used to make the example apparatuses of FIGS. 1, 2, and 3, and, as such, reference is made to those figures. Reference is also made to FIGS. 5A, 5B, and 5C, which show example results of various operations of the method 320. A volume of semiconductor material 22, 222 may be grown, deposited, or otherwise provided as a single, continuous volume of semiconductor material including a first end, a second end, a left side, and a right side, as shown in 322 and seen in FIG. 5A. The volume of semiconductor material 22, 222 may include N-type epitaxial material.

A FET 24, 124, 224 may be made, as shown in 324 and seen in FIGS. 5A, 5B and 5C. In one example, a left well 42A, 242A of the left gate 40A, 240A may be implanted (using, e.g., an ion implanter) or otherwise formed at or adjacent to the left side of the volume of semiconductor material 22, 222 as shown in 326 and seen in FIG. 5A. The left well 42A, 242A may include a lower leg that extends toward the right. The left well 42A, 242A may include P-doped material. A right well 42B, 142B of the right gate 40B, 240B may be similarly implanted or otherwise formed at or adjacent to the right side of the volume of semiconductor material 22, 222, as shown in 326 and seen in FIG. 5A. The right well 42B, 242B may include a lower leg that extends toward the left. The right well 42B, 242B may include P-doped material.

A source 30, 230 may be implanted or otherwise formed at the first end of the volume of semiconductor material 22, 222, between the left and right wells 42A, 42B, 242A, 242B, as shown in 328 and seen in FIG. 5A. The source 30, 230 may provide an entrance for charge carriers (e.g., electrons for N-channel). The source 30, 230 may include N+ material. A drain 32, 232 may be provided spaced apart from the source 30, 230 (e.g., at the second end of the volume of semiconductor material 22, 222), as shown in 330, as seen in FIG. 5A. The drain 32, 232 may provide an exit for the charge carriers. The drain 32, 232 may include N+ substrate material. A channel 38, 238 may be provided by a region of the volume of semiconductor material 22, 222 through which the charge carriers move between the source 30, 230 and the drain 32, 232. The channel 38, 238 may pass between the lower legs of the left and right wells 42A, 42B, 242A, 242B.

A higher doped region of the left gate 40A, 240A may be implanted or otherwise formed at the first end of the volume of semiconductor material 22, 222 and to the left of the source 30, 230 for facilitating controlling movement of the charge carriers through the channel 38, 238, as shown in 332 and seen in FIG. 5A. The higher doped region of the left gate 40A, 240A may be partially embedded within or surrounded by the left well 42A, 242A. A higher doped region of the right gate 40B, 240B may be similarly implanted or otherwise formed at the first end of the volume of semiconductor material 22, 222 and to the right of the source 30, 230 for facilitating controlling movement of the charge carriers through the channel 38, 238, as shown in 332 and seen in FIG. 5A. The higher doped region of the right gate 40B, 240B may be partially embedded within or surrounded by the right well 42B, 242B.

The FET 24, 224 may define the unit cell and the limits thereof. The unit cell may extend laterally from the left edge of the leftmost component (in the examples of FIGS. 1, 2, and 3, the left well 42A, 242B) to the right edge of the rightmost component (in the examples of FIGS. 1, 2, and 3,the right well 42B, 242B). In some applications, there may be many such FET unit cells made and arranged in the single, continuous volume of semiconductor material 22, 222 and, further, there may be several SBDs made in the single, continuous volume of semiconductor material 22, 222 and some or all of these FETs may share the functionality of some or all of these SBDs.

In an example in which the SBD 26, 126 is located outside of the unit cell, as seen in FIGS. 1 and 2 and 5B, the FET 24, 124 may have a planar (FIG. 1) or a trench (FIG. 2) configuration, which primarily affects the configuration of the left and right gates 40A, 40B, 140A, 140B. In another example in which the SBD 226 may be located inside of the unit cell, as seen in FIGS. 3 and 5C, the FET 224 may have a planar configuration, which, again, primarily affects the configuration of the left and right gates 240A, 240B. The SBD 26, 226 may be made at the first end of the volume of semiconductor material 22, 222, as shown in 334 and seen in FIGS. 5B and 5C. The SBD 26, 226 may include one or both of a left SBD 50A, 250A and/or a right SBD 50B, 250B. Forming the left and right SBDs 50A, 50B, 150A, 150B may include depositing or otherwise providing a Schottky material such as aluminum, titanium, molybdenum, platinum, chromium, tungsten, and combinations thereof.

For example, a left SBD may be formed at the first end of the volume of semiconductor material 22, 222, as shown in 336. In one example, the left SBD 50A may be located to the left of the FET 24, i.e., to the left of the left gate 40A (the left well 42A), i.e., outside of the unit cell of the FET 24, as shown in 338 and seen in FIGS. 1 and 5B. In another example, the left SBD 250A may be located within the FET 224, i.e., between the left gate 240A( the left well 242A) and the source 230, adjacent and to the left of the source 230, i.e., inside of the unit cell of the FET 224, as shown in 340 and seen in FIGS. 2 and 5C. Additionally or alternatively, a right SBD may be formed at the first end of the volume of semiconductor material 22, 222, as shown in 342. In one example, the right SBD 50B may be located to the right of the FET 24, i.e., to the right of the right gate 40B (the right well 42B), i.e., outside of the unit cell FET, as shown in 344 and seen in FIGS. 1 and 5B. In another example, the right SBD 250B may be located within the FET 224, i.e., between the right gate 240B (the right well 242B) and the source 230, adjacent and to the right of the source 230, i.e., inside of the unit cell of the FET 224, as shown in 346 and seen in FIGS. 3 and 5C. In yet another example (not shown), one or more SBDs 50A and/or 50B may be located outside of the unit cell and one or more other SBDs 250A and/or 250B may be located inside of the unit cell, i.e., the examples shown in FIGS. 1 or 2 may be combined with the example shown in FIG. 3. As mentioned, locating an SBD inside of the unit cell, as seen in FIGS. 3 and 5C, may provide benefits with regard to field-shaping and transient control, improved dynamic ruggedness, and increased breakdown voltage.

Electrical terminals 52, 252 may be provided on the source 30, 230, the drain 32, 232, the left and right gates 40A, 40B, 240A, 240B, and the left and right SBDs 50A, 50B, 250A, 250B as shown in 348 and seen in FIGS. 5B and 5C, to facilitate applying various voltages.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping characterized as "++" (e.g., P++) will have a relatively higher concentration of dopants than "+" (e.g., P+) doping, "+" doping will have a relatively higher concentration than "-well" (e.g., P-well) doping, and "-well" doping will have a relatively higher concentration of doping than "-" (e.g., P-) doping. In general, doping concentrations (typically measured in parts-per-cubic-centimeter) for contact implants (e.g., sources, drains, body contacts) may be approximately between 5x10^18 and 1x10^22; doping concentrations for channel and threshold forming implants (e.g., P-wells) may be approximately between 5x10^15 and 5x10^17; doping concentrations for shielding implants may be approximately between 5x10^17 and 5x10^19; and doping concentrations for conductivity improvement implants (e.g., N- doping in the junction field-effect transistor neck region of a metal oxide semiconductor field-effect transistor) may be approximately between 1x10^17 and 1x10^19.

Relatedly, a structure or region may contain two or more different doping doses. In various examples, dopant concentrations within a given structure or region may vary within the example range described above for the corresponding region type. Dopant concentration may vary according to a gradient that gradually decreases as the depth of the implant increases. Further, one with ordinary skill in the art will recognize that some P-wells may contain a lower dose P-well portion and a higher dose unclamped inductive switching portion. Dopant concentration variation within a given structure or region may result from normal manufacturing variance, may be by design, or may otherwise arise without departing from the spirit of the present disclosure.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

What is claimed is:

1. An apparatus comprising:
a volume of semiconductor material including a first end and laterally spaced left and right sides;
a field-effect transistor (FET) including –
a source located at the first end of the volume of semiconductor material,
a drain located spaced apart from the source,
a gate located adjacent the first end of the volume of semiconductor material, with the source and the gate being spaced apart to cooperatively define a FET until cell located between the left and right sides of the volume of the volume of semiconductor material; and
a first Schottky barrier diode (SBD) located at the first end of the volume of semiconductor material and outside of and adjacent to the FET unit cell.

2. The apparatus of claim 1,
the FET being a junction field-effect transistor (JFET).

3. The apparatus of claim 2,
the JFET being a planar JFET.

4. The apparatus of claim 2,
the JFET being a trench JFET.

5. The apparatus of claim 1,
the first SBD including a Schottky material selected from the group consisting of: aluminum, titanium, molybdenum, platinum, chromium, tungsten, and combinations thereof.

6. The apparatus of claim 1,
the gate including spaced apart left and right gates,
the source being located between the left and right gates.

7. The apparatus of claim 6,
the left gate presenting a leftmost margin closest to the left side of the volume of semiconductor material,
the right gate presenting a rightmost margin closest to the right side of the volume of semiconductor material,
the FET unit cell being defined between the leftmost margin of the left gate and the rightmost margin of the right gate.

8. The apparatus of claim 7,
the leftmost margin of the left gate being spaced from the left side of the volume of semiconductor material,
the rightmost margin of the right gate being spaced from the right side of volume of semiconductor material.

9. The apparatus of claim 6,
the first SBD being a left SBD located outside of the FET unit cell adjacent to the left gate; and
a right SBD located at the first end of the volume of semiconductor material and outside of the FET unit cell adjacent to the right gate.

10. The apparatus of claim 9,
the left gate presenting a leftmost margin closest to and spaced from the left side of the volume of semiconductor material,
the right gate presenting a rightmost margin closest to and spaced from the right side of the volume of semiconductor material,
the FET unit cell being defined between the leftmost margin of the left gate and the rightmost margin of the right gate,
the left SBD being located between the leftmost margin of the left gate and the left side of the volume of semiconductor material,
the right SBD being located between the rightmost margin of the right gate and the right side of the volume of semiconductor material.

11. The apparatus of claim 1,
the volume of semiconductor material comprising an N-type material,
the source comprising a N+ material,
the drain comprising N+ material,
the gate including a first region comprising a P+ material and a second region comprising a P material.

12. The apparatus of claim 1,
the first SBD being a left SBD located outside of the FET unit cell adjacent to the left side of the volume of semiconductor material; and
a right SBD located at the first end of the volume of semiconductor material and outside of the FET unit cell adjacent to the right side of the volume of semiconductor material.

13. A method of making an apparatus, the method comprising:
providing a volume of semiconductor material to present a first end and laterally spaced left and right sides;
making a first field-effect transistor (FET), including –
forming a source at the first end of the volume of semiconductor material,
providing a drain spaced apart from the source,
forming a gate adjacent the first end of the volume of semiconductor material spaced from the source, such that the source and the gate cooperatively define a FET until cell located between the left and right sides of the volume of the volume of semiconductor material; and
making a first Schottky barrier diode (SDB) at the first end of the volume of semiconductor material and outside of and adjacent to the FET unit cell.

14. The method of claim 13,
the operation of forming the gate including providing spaced apart left and right gates, such that the source is located between the left and right gates.

15. The method of claim 14,
the operation of forming the left gate including spacing a leftmost margin of the left gate from the left side of the volume of semiconductor material,
the operation of forming the right gate including spacing a rightmost margin of the right gate from the right side of the volume of semiconductor material, with the FET unit cell being defined between the leftmost margin of the left gate and the rightmost margin of the right gate.

16. The method of claim 15,
the operation of making the first SDB including forming the first SBD between the leftmost margin of the left gate and the left side of the volume of semiconductor material; and
making a second SBD at the first end of the volume of semiconductor material outside of the FET unit cell between the rightmost margin of the right gate and the right side of the volume of semiconductor material.

17. The method of claim 13,
the operation of making the first SDB including forming the first SBD adjacent the left side of the volume of semiconductor material; and
making a second SBD at the first end of the volume of semiconductor material outside of the FET unit cell adjacent the right side of the volume of semiconductor material.

18. The method of claim 13,
wherein the first field-effect transistor is a junction field-effect transistor (JFET),
the operation of providing the volume of semiconductor material being performed so that the first end is planar,
the operations of forming the source and gate including positioning the source and the gate at the first end, such that the JFET is a planar JFET.

19. The method of claim 13,
wherein the first field-effect transistor is a junction field-effect transistor (JFET); and
etching a trench into the first end of the volume of semiconductor material on opposite sides of the source,
the operation of forming the gate including providing spaced apart left and right gates in the trench on opposite sides of the source, such that the JFET is a trench JFET.

20. The method of claim 13,
the operation of making the first SBD including placing a Schottky material on the first end of the volume of semiconductor material, wherein the Schottky material is selected from the group consisting of: aluminum, titanium, molybdenum, platinum, chromium, tungsten, and combinations thereof.
